(19) United States
(12) Patent Application Publication
(10) Pub. No.: US 2026/0020466 A1
(43) Pub. Date: Jan. 15, 2026

(54) DISPLAY DEVICE

(71) Applicant: Japan Display Inc., Tokyo (JP)

(72) Inventors: Hiroshi TABATAKE, Tokyo (JP); Hiroyuki KIMURA, Tokyo (JP)

(73) Assignee: Japan Display Inc., Tokyo (JP)

(21) Appl. No.: 19/263,654

(22) Filed: Jul. 9, 2025

(30) Foreign Application Priority Data
Jul. 10, 2024 (JP) 2024-111122

(51) Int. Cl. H10K 59/40; H10K 59/122; H10K 59/35; H10K 59/80

(52) U.S. Cl. CPC H10K 59/40; H10K 59/122; H10K 59/873; H10K 59/352; H10K 59/353

(57) ABSTRACT

According to one embodiment, a display devices includes, a first lower electrode, a second lower electrode, a third lower electrode, organic layers respectively provided on the first lower electrode, the second lower electrode, and the third lower electrode, an upper electrode, and a detection electrode. An interval between the first lower electrode and the second lower electrode is greater than an interval along between the second lower electrode and the third lower electrode. The detection electrode includes a first segment located between the first lower electrode and the second lower electrode, and does not include a segment between the second lower electrode and the third lower electrode.

### CROSS-REFERENCE TO RELATED APPLICATION

This application is based upon and claims the benefit of priority from Japanese Patent Application No. 2024-111122, filed Jul. 10, 2024, the entire contents of which are incorporated herein by reference.

### FIELD

Embodiments described herein relate generally to a display device.

### BACKGROUND

Recently, display devices to which an organic light emitting diode (OLED) is applied as a display element and which comprise touch sensor function for detecting contact or approach of an object to a display area have been put into practical use. Improvement of display quality in such display devices has been demanded.

### BRIEF DESCRIPTION OF THE DRAWINGS

FIG. 1 is a view showing a configuration example of a display device DSP.

FIG. 2 is a schematic plan view showing elements for implementing the touch sensor function.

FIG. 3 is a plan view schematically showing a configuration example of the layout of pixels PX and the layout of a detection electrode DT in a display area DA.

FIG. 4 is a schematic cross-sectional view showing the display device DSP along the A-B line of FIG. 3.

FIG. 5 is a schematic cross-sectional view of the display device DSP along the C-D line of FIG. 3.

FIG. 6 is a cross-sectional view for describing another effect in the display device DSP.

FIG. 7 is a plan view schematically showing another configuration example of the layout of the pixels PX and the layout of the detection electrode DT in the display area DA.

FIG. 8 is a plan view schematically showing another configuration example of the layout of the pixels PX and the layout of the detection electrode DT in the display area DA.

FIG. 9 is a plan view schematically showing another configuration example of the layout of the pixels PX and the layout of the detection electrode DT in the display area DA.

FIG. 10 is a schematic cross-sectional view of the display device DSP along the E-F line of FIG. 9.

FIG. 11 is a schematic cross-sectional view of the display device DSP along the G-H line of FIG. 9.

### DETAILED DESCRIPTION

Embodiments described herein aim to provide a display device that comprises a touch sensor function and is configured to improve display quality.

In general, according to one embodiment, a display devices includes, a first lower electrode, a second lower electrode, and a third lower electrode that are arranged in order in a first direction in a display area for displaying an image, organic layers respectively provided on the first lower electrode, the second lower electrode, and the third lower electrode and each including a light emitting layer, an upper electrode provided on the organic layer, and a detection electrode for detecting contact or approach of an object to the display area. An interval along the first direction between the first lower electrode and the second lower electrode is greater than an interval along the first direction between the second lower electrode and the third lower electrode. The detection electrode extends in a second direction intersecting the first direction, includes a first segment located between the first lower electrode and the second lower electrode in plan view, and does not include a segment between the second lower electrode and the third lower electrode.

Embodiments can provide a display device that comprises a touch sensor function and is configured to improve display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to one another are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

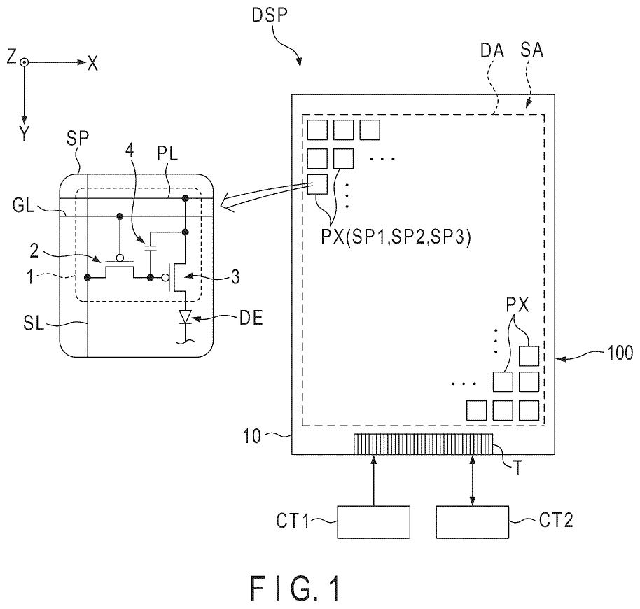

FIG. 1 is a view showing a configuration example of a display device DSP.

The display device DSP comprises a display panel 100. The display panel 100 has a display area DA for displaying an image and a surrounding area SA around the display area DA on an insulating substrate 10. The substrate 10 may be either a glass substrate or a resinous substrate having flexibility.

In the illustrated example, the shape of the substrate 10 is a rectangle in plan view. The shape of the substrate 10 in plan view is not limited to a rectangle and may be another shape such as a square, a circle, or an oval.

The display area DA comprises a plurality of pixels PX arrayed in a matrix in the first direction X and the second direction Y. Each pixel PX includes a plurality of subpixels SP that display different colors. For example, each pixel PX includes a subpixel SP1 which displays the first color, a subpixel SP2 which displays the second color, and a subpixel SP3 which displays the third color. The first color, the second color, and the third color are different colors. Each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display device DSP.

The display device DSP further comprises a display controller CT1 for controlling the image display in the display area DA and a detection controller CT2 for implementing the touch sensor function of detecting contact or approach of an object to the display area DA. Each of the display controller CT1 and the detection controller CT2 is mounted, for example, on the flexible printed circuit board described above. As another example, the display controller CT1 and the detection controller CT2 may be mounted in the surrounding area SA.

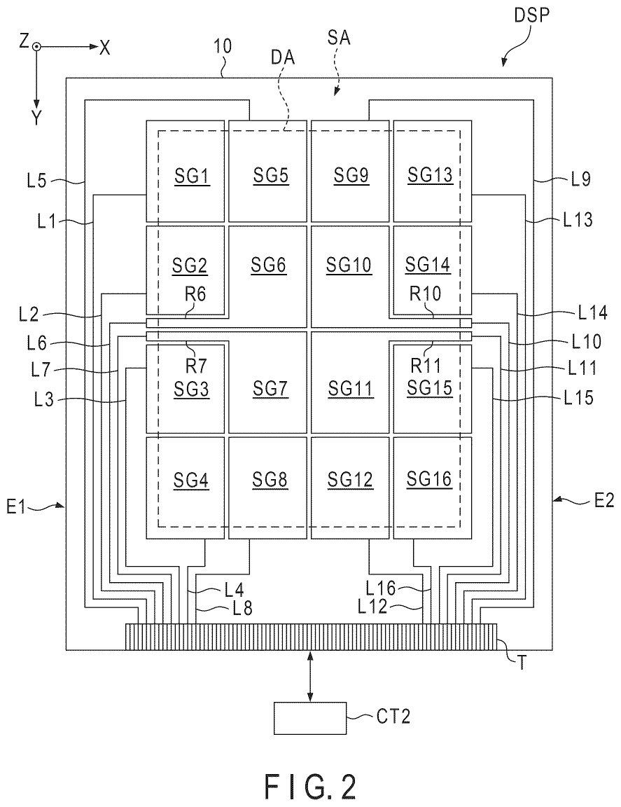

FIG. 2 is a schematic plan view showing elements for implementing the touch sensor function.

The display device DSP comprises a plurality of sensor modules SG, which function as electrodes for the touch sensor. These sensor modules SG are constituted by a detection electrode to be described later.

In the illustrated example, 16 sensor modules SG (SG1 to SG16) overlapping the display area DA are arranged in a matrix consisting of 4 columns×4 rows. The number and the layout of the sensor modules SG are not limited to this example.

The sensor modules SG1 to SG16 are electrically connected to the terminal portion T via respective leads L1 to L16 provided in the surrounding area SA. In the illustrated example, the leads L1 to L3 and L5 to L7 are provided between the display area DA and an end portion E1 of the substrate 10 in the left side of the figure and extend to the terminal portion T. Further, the leads L9 to L11 and L13 to L15 are provided between the display area DA and an end portion E2 of the substrate 10 in the right side of the figure and extend to the terminal portion T. The leads L4, L8, L12, and L16 are provided between the display area DA and the terminal portion T.

The sensor modules SG6, SG7, SG10, and SG11 are surrounded by the other sensor modules SG. In the illustrated example, relay portions R6, R7, R10, and R11 are provided in the display area DA to enable the respective connections between these sensor modules SG6, SG7, SG10, and SG11 and the leads L6, L7, L10, and L11.

The relay portions R6, R7, R10, and R11 electrically connect the sensor modules SG6, SG7, SG10, and SG11 to the leads L6, L7, L10, and L11, respectively. The relay portions R6 and R7 are located between the sensor modules SG2 and SG3. The relay portions R10 and R11 are located between the sensor modules SG14 and SG15.

The detection controller CT2 supplies each of the sensor modules SG1 to SG16 with drive signals through the leads L1 to L16 with a predetermined period. These drive signals charge the capacity of the sensor modules SG1 to SG16 themselves.

After the supply of the drive signal, the detection controller CT2 reads detection signals (output voltage) from the sensor modules SG1 to SG16 through the leads L1 to L16. The detection signal corresponds to, for example, the amount of charge stored in the capacity of the sensor modules SG1 to SG16 themselves.

Among the sensor modules SG1 to SG16 arrayed in an X-Y plane (a detection surface), the value of the detection signal differs between the sensor modules SG that are close to an object such as a finger of the user and the other sensor modules SG. Thus, the detection controller CT2 can detect location information of the object based on the detection signal of each of the sensor modules SG.

When the display device DSP operates, a display period for image display and a sensor period for touch detection are alternately repeated. In each display period, display voltage is written to each of the display elements DE. In each sensor period, supply of drive signals to the sensor modules SG1 to SG16 and reading of drive signals from the sensor modules SG1 to SG16 are performed. The display voltage written in the display period is maintained in the sensor period as well.

The detection system using the sensor modules SG1 to SG16 and the operation of the display device DSP are not limited to the example shown here.

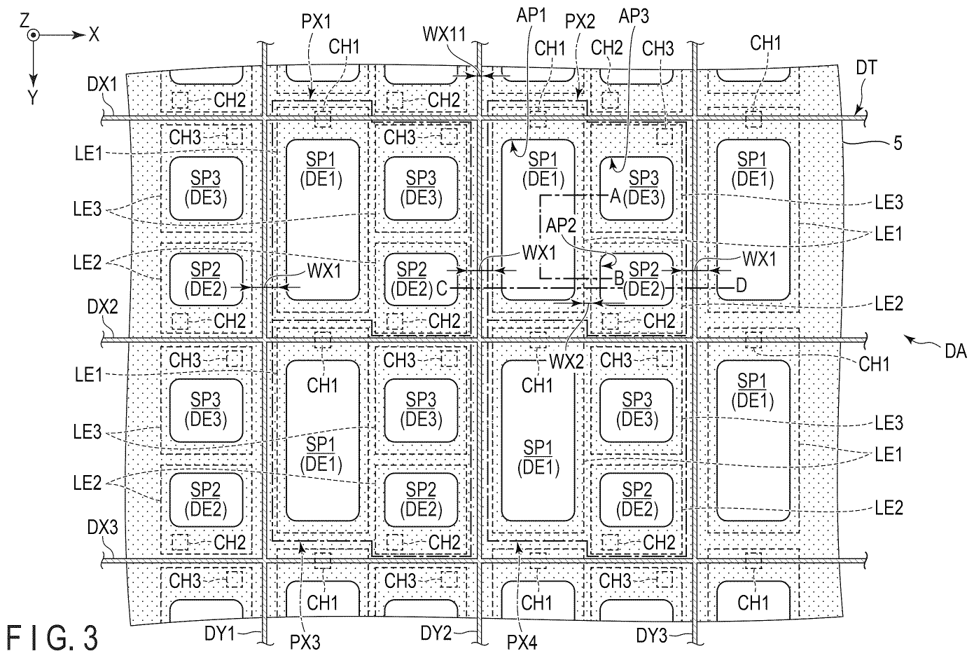

FIG. 3 is a plan view schematically showing a configuration example of the layout of the pixels PX and the layout of the detection electrode DT in the display area DA.

The following description focuses on four pixels: pixels PX1, PX2, PX3, and PX4 arrayed in a matrix in the first direction X and the second direction Y in the display area DA.

The pixels PX1 and PX2 are arranged in the first direction X. The pixels PX3 and PX4 are arranged in the first direction X. The pixels PX1 and PX3 are arranged in the second direction Y. The pixels PX2 and PX4 are arranged in the second direction Y.

Each of the pixels PX1, PX2, PX3, and PX4 includes the subpixels SP1, SP2, and SP3. In the illustrated example, the subpixels SP2 and SP3 are arranged in the second direction Y. The subpixels SP2 and SP1 are arranged in the first direction X. The subpixels SP3 and SP1 are arranged in the first direction X.

When the subpixels SP1, SP2, and SP3 are arranged in this layout, in the display area DA, a column in which the subpixels SP2 and SP3 are alternately arranged in the second direction Y and a column in which a plurality of subpixels SP1 are arranged in the second direction Y are formed. These columns are alternately arranged in the first direction X. The layout of the subpixels SP1, SP2, and SP3 is not limited to the illustrated example.

An insulating layer 5 is provided in the display area DA. The insulating layer 5 has apertures AP1, AP2, and AP3 in the subpixels SP1, SP2, and SP3, respectively. The insulating layer 5 having these apertures AP1, AP2, and AP3 may be called a rib. In the illustrated example, the planer size of the aperture AP1, the planar size of the aperture AP2, and the planar size of the aperture AP3 differ from one another. The planer size of the aperture AP1 is greater than that of the aperture AP3. The planer size of the aperture AP3 is greater than that of the aperture AP2.

The subpixels SP1, SP2, and SP3 comprise display elements DE1, DE2, and DE3, respectively, as the display elements DE. The display element DE comprises a lower electrode, an upper electrode facing the lower electrode, and an organic layer located between the lower electrode and the upper electrode. FIG. 3 shows the lower electrode but omits the illustration of the upper electrode and the organic layer. For example, the lower electrode corresponds to the anode of the display element DE, and the upper electrode corresponds to the cathode of the display element DE.

The display element DE1 comprises a lower electrode LE1 overlapping the aperture AP1. The peripheral portion of the lower electrode LE1 overlaps the insulating layer 5 in plan view. The lower electrode LE1 is electrically connected to the drive transistor 3 shown in FIG. 1 through a contact hole CH1.

The display element DE2 comprises a lower electrode LE2 overlapping the aperture AP2. The peripheral portion of the lower electrode LE2 overlaps the insulating layer 5 in plan view. The lower electrode LE2 is electrically connected to the drive transistor 3 shown in FIG. 1 through a contact hole CH2.

The display element DE3 comprises a lower electrode LE3 overlapping the aperture AP3. The peripheral portion of the lower electrode LE3 overlaps the insulating layer 5 in plan view. The lower electrode LE3 is electrically connected to the drive transistor 3 shown in FIG. 1 through a contact hole CH3.

The detection electrode DT constitutes the sensor modules shown in FIG. 2 and is formed into a grating shape surrounding each of the pixels PX1, PX2, PX3, and PX4 in plan view. That is, the detection electrode DT includes a plurality of segments DX1, DX2, and DX3, which extend in the first direction X and a plurality of segments DY1, DY2, and DY3, which extend in the second direction Y. The segments DX1, DX2, and DX3 are arranged in this order in the second direction Y and adjacent to each other. The segments DY1, DY2, and DY3 are arranged in this order in the first direction X and adjacent to each other. The segments DX1, DX2, and DX3 and the segments DY1, DY2, and DY3 are connected to each other.

As described above, the touch sensor function is implemented by detecting a capacity variation in the sensor modules constituted by the detection electrode DT. Thus, the detection electrode DT is preferably formed across as wide an area as possible for ensuring the capacity of the detection electrode DT.

This detection electrode DT does not have a segment between the subpixels SP1 and SP2 and between the subpixels SP1 and SP3 in each of the pixels PX1, PX2, PX3, and PX4.

From another viewpoint, the detection electrode DT does not have a segment between the lower electrodes LE1 and LE2 and between the lower electrodes LE1 and LE3 in plan view in each of the pixels PX1, PX2, PX3, and PX4.

The segment DY2 is located between the pixels PX1 and PX2, between the subpixel SP2 of the pixel PX1 and the subpixel SP1 of the pixel PX2, and between the subpixel SP3 of the pixel PX1 and the subpixel SP1 of the pixel PX2. The segment DY2 is located between the pixels PX3 and PX4, between the subpixel SP2 of the pixel PX3 and the subpixel SP1 of the pixel PX4, and between the subpixel SP3 of the pixel PX3 and the subpixel SP1 of the pixel PX4.

From another view point, the segment DY2 is located at an approximate center between the lower electrode LE2 of the pixel PX1 and the lower electrode LE1 of the pixel PX2 and an approximate center between the lower electrode LE3 of the pixel PX1 and the lower electrode LE1 of the pixel PX2 in plan view. Further, the segment DY2 is located at an approximate center between the lower electrode LE2 of the pixel PX3 and the lower electrode LE1 of the pixel PX4 and an approximate center between the lower electrode LE3 of the pixel PX3 and the lower electrode LE1 of the pixel PX4.

For example, the pixel PX2 is surrounded by the segments DX1 and DX2 and the segments DY2 and DY3. That is, any of the subpixel SP1 or the lower electrode LE1, the subpixel SP2 or the lower electrode LE2, and the subpixel SP3 or the lower electrode LE3 are located between the segments DY2 and DY3 in the first direction X. Further, any of the subpixel SP1 or the lower electrode LE1, the subpixel SP2 or the lower electrode LE2, and the subpixel SP3 or the lower electrode LE3 are located between the segments DX1 and DX2 in the second direction Y.

An interval WX1 along the first direction X between the lower electrode LE2 of the pixel PX1 and the lower electrode LE1 of the pixel PX2 is greater than an interval WX2 along the first direction X between the lower electrode LE1 of the pixel PX2 and the lower electrode LE2 of the pixel PX2 (WX1>WX2). That is, among the plurality of segments constituting the detection electrode DT, the segment DY extending in the second direction Y is provided to overlap an area with a relatively wide width between the pixels PX adjacent to each other in the first direction X. On the other hand, the segment DY is not provided in an area with a relatively narrow width in each pixel PX.

A width WX11 along the first direction X of the segment DY extending in the second direction Y is smaller than the interval WX1 (WX11<WX1). Thus, for example, the segment DY2 does not entirely overlap the area between the lower electrodes LE1 and LE2 in plan view.

With respect to the segment DX2, the segment DX2 overlaps the lower electrode LE1 of each of the pixels PX3 and PX4, is located between the lower electrode LE2 of the pixel PX1 and the lower electrode LE3 of the pixel PX3, and is located between the lower electrode LE2 of the pixel PX2 and the lower electrode LE3 of the pixel PX4 in plan view.

Further, the segment DX2 overlaps the contact hole CH1 and is located between the contact holes CH2 and CH3 in plan view. In this manner, the contact holes CH1, CH2, and CH3 are provided in the vicinity of the segments DX linearly extending along the first direction X. Further, among various lines for driving the pixel circuit 1 shown in FIG. 1, the lines such as the scanning lines GL extending in the first direction X are provided in the vicinity of the segments DX.

The segments DY linearly extending along the second direction Y do not overlap any of the lower electrodes.

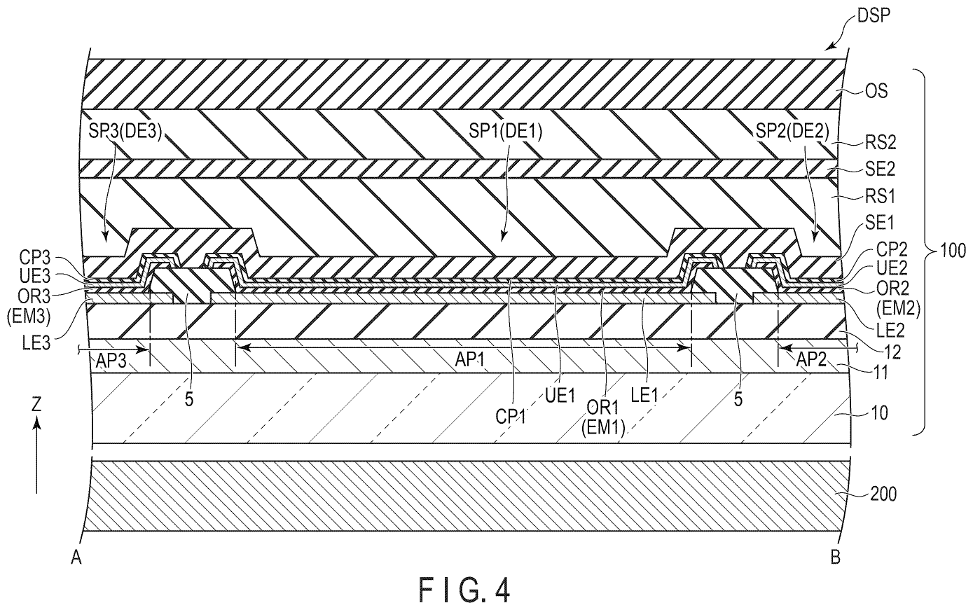

FIG. 4 is a schematic cross-sectional view showing the display device DSP along the A-B line of FIG. 3.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

The insulating layer 12 is provided on the circuit layer 11. For example, the insulating layer 12 is an organic insulating layer that planarizes the uneven parts formed by the circuit layer 11.

The lower electrode LE1 of the subpixel SP1, the lower electrode LE2 of the subpixel SP2, and the lower electrode LE3 of the subpixel SP3 are provided on the insulating layer 12 and are spaced apart from one another.

The insulating layer 5 is an inorganic insulating layer or an organic insulating layer and is provided on the insulating layer 12 and the lower electrodes LE1, LE2, and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the insulating layer 5. The contact holes CH1, CH2, and CH3 shown in FIG. 3 are formed on the insulating layer 12, but illustration of them is omitted here.

The organic layer OR1 contacts the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1.

The organic layer OR2 contacts the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2.

The organic layer OR3 contacts the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3.

In the illustrated example, the subpixel SP1 has a cap layer CP1, the subpixel SP2 has a cap layer CP2, and the subpixel SP3 has a cap layer CP3. The cap layers CP1, CP2, and CP3 function as optical adjustment layers, which improve the extraction efficiency of light emitted from the organic layers OR1, OR2, and OR3, respectively. The cap layer CP1 is provided on the upper electrode UE1. The cap layer CP2 is provided on the upper electrode UE2. The cap layer CP3 is provided on the upper electrode UE3. The cap layers CP1, CP2, and CP3 may be omitted.

The sealing layer SE1 is provided to cover the cap layers CP1, CP2, and CP3 and the insulating layer 5.

A transparent resin layer RS1 covers the sealing layer SE1. The sealing layer SE2 covers the resin layer RS1. A transparent resin layer RS2 covers the sealing layer SE2. An optical sheet OS is, for example, a polarizer and is bonded to the resin layer RS2.

Each of the sealing layers SE1 and SE2 is formed of an inorganic insulating material such as a silicon nitride (SiNx), a silicon oxide (SiOx), a silicon oxynitride (SiON), or an aluminum oxide (Al₂O₃).

Each of the lower electrodes LE1, LE2, and LE3 is, for example, a multilayer body having a transparent layer formed of an oxide conductive material such as indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, EM3 are formed of materials different from one another. For example, the light emitting layer EM1 is formed of a material that emits light in a blue wavelength range. The light emitting layer EM2 is formed of a material that emits light in a red wavelength range. The light emitting layer EM3 is formed of a material that emits light in a green wavelength range.

Each of the organic layers OR1, OR2, and OR3 has a plurality of functional layers such as a hole injection layer, a hole transport layer, an electron blocking layer, a hole blocking layer, an electron transport layer, and an electron injection layer.

Each of the upper electrodes UE1, UE2, and UE3 is formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from one another.

An external device 200 faces the display panel 100 and is provided on the rear side of the display panel 100 in the third direction Z. The external device 200 is, for example, an optical device configured to receive light passing through the display panel 100 and output electric signals. The external device 200 may comprise an illumination sensor or a camera. Alternatively, the external device 200 may be a communication device configured to transmit or receive radio waves via the display panel 100.

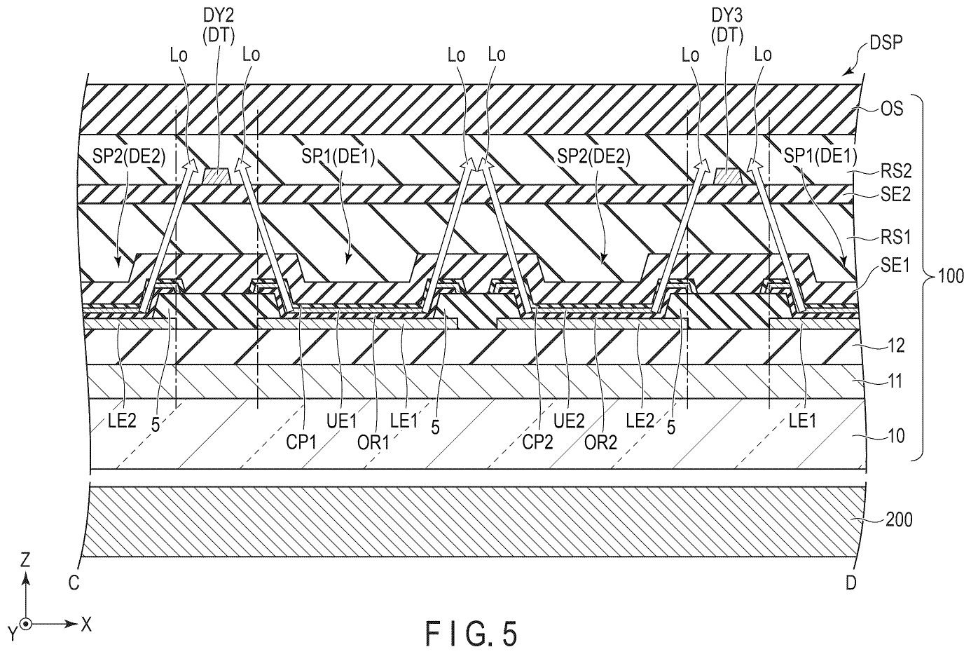

FIG. 5 is a schematic cross-sectional view of the display device DSP along the C-D line of FIG. 3.

The detection electrode DT including the segments DY2 and DY3 is provided on the sealing layer SE2 and is covered with the resin layer RS2. For example, the detection electrode DT is a multilayer body having an aluminum layer formed of an aluminum-based material and a titanium layer formed of a titanium-based material.

For example, in the subpixels SP1 and SP2 located at the center of the figure, the segments DY extending in the second direction Y are not provided in an area between the lower electrodes LE1 and LE2 that are adjacent to each other in the first direction X with a relatively small interval. Thus, light Lo emitted from each of the subpixels SP1 and SP2 is less susceptible to shielding by the segment DY.

As a comparative example, the following describes a case where the segment DY of the detection electrode DT is provided in the area between the lower electrodes LE1 and LE2 that are adjacent to each other with a relatively small interval. An angle between the position at which the display device DSP is observed and a normal (a line parallel to the third direction Z) of the display device DSP is defined as an observation angle. As the observation angle increases in the X-Z plane, part of the light Lo that is emitted from the subpixel SP1 or the subpixel SP2 and shielded by the segment DY increases. Thus, luminance of displayed images decreases. When part of the light Lo emitting from each of the subpixels SP1, SP2, and SP3 is shielded by the segments DY, color chromaticity of the displayed images varies.

In contrast, the above configuration example allows the light Lo emitted from each of the subpixels to be less susceptible to shielding by the detection electrode DT, suppressing undesirable decreases in luminance and undesirable variations in color chromaticity.

Further, as described with reference to FIG. 3, the segments DX extending in the first direction X are provided in the vicinity of the contact holes CH1, CH2, and CH3 and are sufficiently farther from each of the apertures AP1, AP2, and AP3. Thus, even when the observation angle increases in the Y-Z plane, the light Lo emitted from each of the subpixels is less susceptible to shielding by the detection electrode DT and thus undesirable decreases in luminance and undesirable variations in color chromaticity can be suppressed.

Thus, the display quality can be improved.

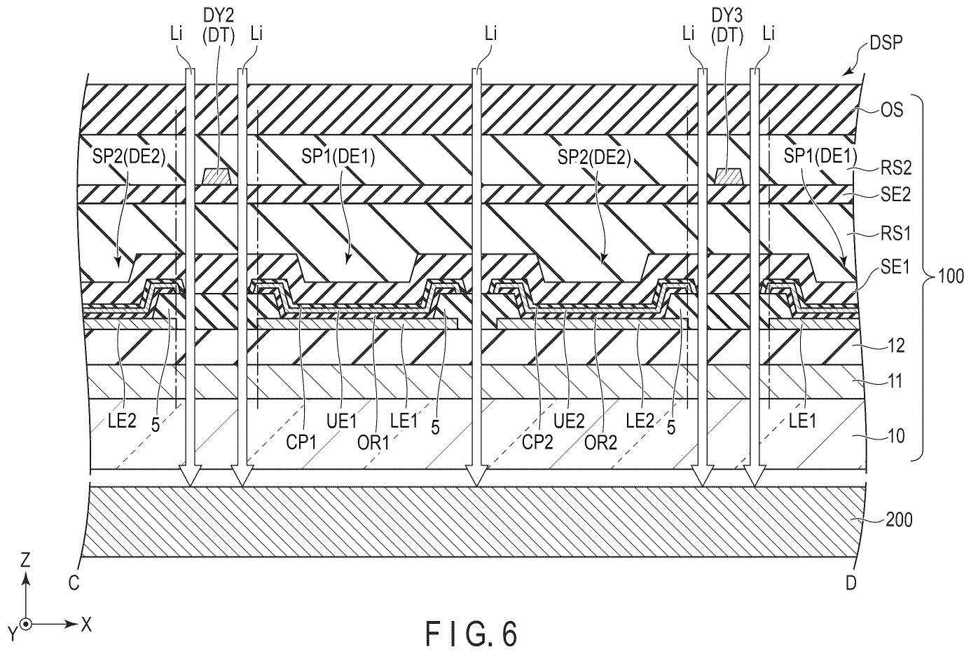

FIG. 6 is a cross-sectional view for describing another effect in the display device DSP.

In the subpixels SP1 and SP2 located at the center of the figure, the transmission area transmitting the light Li can be formed between the lower electrodes LE1 and LE2. In cases where the external device 200 is the optical device, the external device 200 can receive the light Li having passed through the transmissive area. Further, even when the segments DY extending in the second direction Y are shifted in the first direction X at the time of forming the detection electrode DT, the transmissive area does not overlap the segments DY. Thus, the light Li can be reliably received by the external device 200.

Further, in the subpixels SP1 and SP2 in the left side of the figure, the segment DY2 is provided to overlap the area between the lower electrodes LE1 and LE2. Similarly, in the subpixels SP1 and SP2 in the right side of the figure, the segment DY3 is provided to overlap the area between the lower electrodes LE1 and LE2. As described above, the width of each of the segment DY extending in the second direction Y is smaller than the interval between the lower electrodes LE1 and LE2. Thus, the segment DY does not completely close the area between the lower electrodes LE1 and LE2. Thus, the area transmitting light Li can be formed. Thus, the external device 200 can receive the light Li in the area in which the segment DY is provided as well.

Thus, the external device 200 can achieve desired performance.

For example, in cases where the external device 200 is the illumination sensor, the illumination sensor measures the luminance of the light Li made incident through the display device DSP (in other words, external light). A function of automatically adjusting the brightness of the display device DSP according to luminance measured by the illumination sensor can be implemented. For example, the function sets the brightness of the display device DSP higher in a brighter environment and sets the brightness of the display device DSP lower in a darker environment.

The above describes the cases where the external device 200 is the optical device. Even in cases where the external device 200 is the communication device, the transmissive area is formed as an area allowing radio waves to pass through. Thus, the external device 200 can reliably transmit or receive radio waves, achieving desired performance.

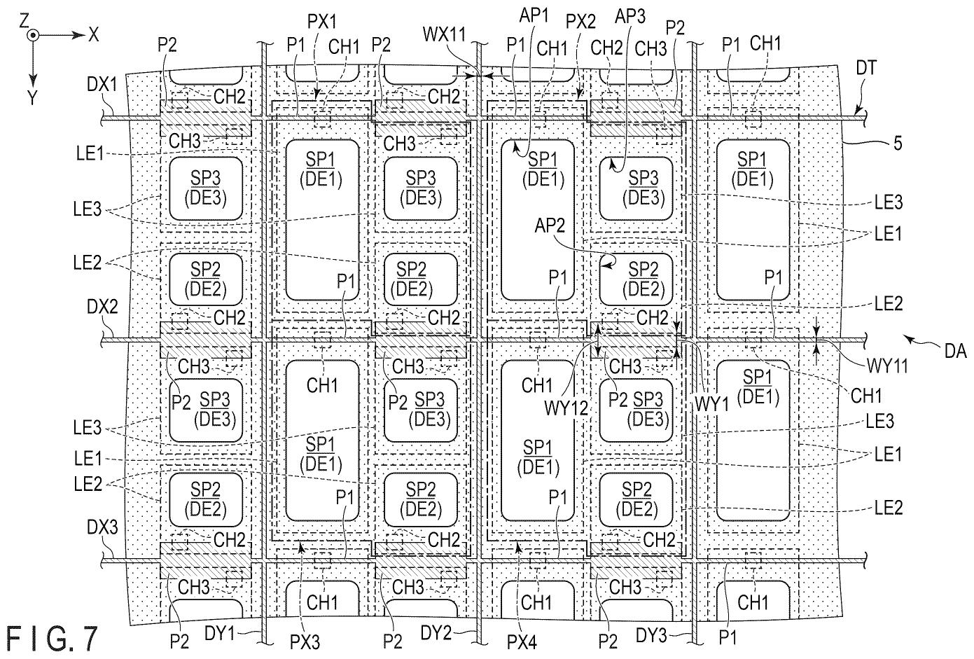

FIG. 7 is a plan view schematically showing another configuration example of the layout of the pixels PX and the layout of the detection electrode DT in the display area DA.

The configuration example shown in FIG. 7 differs from the configuration example shown in FIG. 3 in that the segment DX extending in the first direction X is locally wide. In the illustrated example, each of the segments DX1, DX2, and DX3 has a first portion P1 having a first width WY11 along the second direction Y and a second portion P2 having a second width WY12 along the second direction Y. The second width WY12 is greater than the first width WY11 (WY12>WY11). An interval WY1 along the second direction Y between the lower electrodes LE2 and LE3 is greater than the first width WY11 and is smaller than the second width WY12 (WY11<WY1<WY12).

For example, the first portion P1 of the segment DX2, which is illustrated, is adjacent to the lower electrode LE1 of the pixel PX2 in the second direction Y. The second portion P2 of the segment DX2 is adjacent to the lower electrode LE2 of the pixel PX2 and the lower electrode LE3 of the pixel PX4 and is located between these lower electrodes LE2 and LE3 in the second direction Y. Part of the first portion P1 overlaps at least part of the contact hole CH1 in plan view. Part of the second portion P2 overlaps part of each of the contact holes CH2 and CH3 in plan view.

Expanding the second portions P2 of the segments DX extending in the first direction X can increase the installation area of the detection electrode DT and sufficiently ensure the capacity of the detection electrode DT. Thus, the detection sensitivity of the detection electrode DT can be improved.

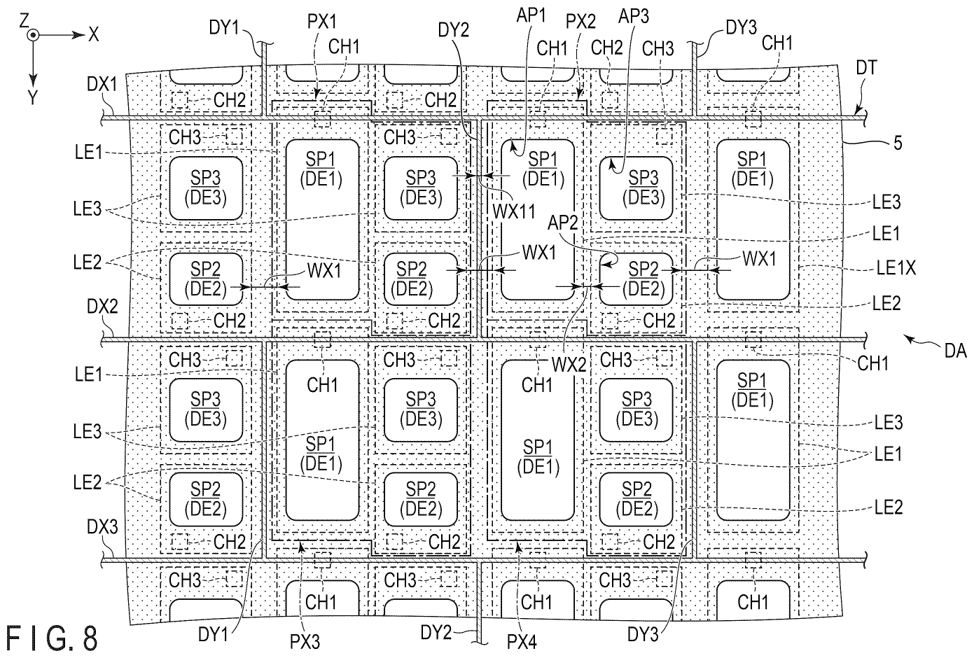

FIG. 8 is a plan view schematically showing another configuration example of the layout of the pixels PX and the layout of the detection electrode DT in the display area DA.

The configuration example shown in FIG. 8 differs from the configuration example shown in FIG. 3 in that the segment DY extending in the second direction Y is formed discontinuously. Each of the segments DX extending in the first direction X is formed continuously.

For example, in the area between the segments DX1 and DX2, the segments DY1 and DY3 are not provided, but the segment DY2 is provided between the pixels PX1 and PX2. That is, the detection electrode DT does not have a segment on the side opposite to the segment DY2 across the pixel PX1, and does not have a segment on the side opposite to the segment DY2 across the pixel PX2. For example, in a lower electrode LE1X provided in the right side with respect to the lower electrodes LE2 and LE3 and adjacent to these lower electrodes of the pixel PX2, segments extending in the second direction Y are not provided in the area between the lower electrodes LE2 and LE1X and the area between the lower electrodes LE3 and LE1X. The interval WX1 along the first direction X between the lower electrodes LE2 and LE1X is greater than the interval WX2 along the first direction X between the lower electrodes LE1 and LE2 of the same pixel.

The segment DY2 does not extend beyond the segments DX1 or DX2. Thus, the segments DY2 and DX1 intersect each other to form a T-letter shape. Similarly, the segments DY2 and DX2 intersect each other to form a T-letter shape.

In the area between the segments DX2 and DX3, the segments DY1 and DY3 are provided, but the segment DY2 is not provided. Thus, the detection electrode DT does not have a segment between the pixels PX3 and PX4. Two pixels, the pixels PX3 and PX4 adjacent to each other in the first direction X are surrounded by the segments DX2 and DX3 and the segments DY1 and DY3.

Each of the segments DY1 and DY3 does not extend beyond the segments DX2 or DX3. Thus, the segments DY1 and DX2 intersect each other to form a T-letter shape. Similarly, the segments DY1 and DX3 intersect each other to form a T-letter shape. Further, the segments DY3 and DX2 intersect each other to form a T-letter shape. Similarly, the segments DY3 and DX3 intersect each other to form a T-letter shape.

In this manner, three sides of each of the pixels PX having a rectangular shape are surrounded by the segments of the detection electrode DT. However, no segment is provided along the other one side. Thus, compared to the configuration example shown in FIG. 3 in which the four sides are surrounded by the segments of the detection electrode DT, this configuration can suppress the degradation in display quality even when observation angle is broader.

Furthermore, unlike the configuration example shown in FIG. 3 in which the segment DY overlaps the entire area between the lower electrodes LE1 and LE2 adjacent to each other at the relatively large interval WX1, the segment DY of the configuration does not overlap about the half of the area. Thus, the transmissive area can be expanded. Thus, the external device 200 can achieve desired performance.

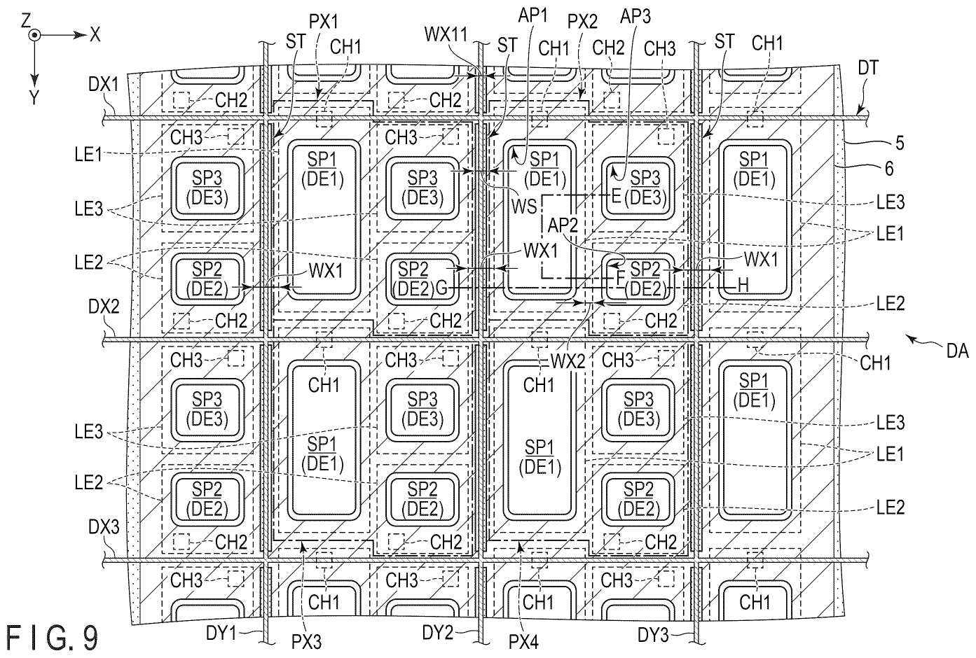

FIG. 9 is a plan view schematically showing another configuration example of the layout of the pixels PX and the layout of the detection electrode DT in the display area DA.

The configuration example shown in FIG. 9 differs from the configuration example shown in FIG. 3 in that a partition 6 is provided.

The partition 6 entirely overlaps the insulating layer 5 and has a planar shape similar to that of the insulating layer 5. In other words, the partition 6 has an aperture in each of the subpixels SP1, SP2, and SP3. From another viewpoint, each of the insulating layer 5 and the partition 6 has a lattice shape in plan view and surrounds each of the display elements DE1, DE2, and DE3, or each of the lower electrodes LE1, LE2, and LE3. The partition 6 is formed of a conductive material and serves as a wire for supplying the upper electrodes of each of the display elements DE1, DE2, and DE3 with a common voltage.

In addition, the partition 6 has a plurality of slits ST in plan view. Each of the slits ST is located between two adjacent pixels in the first direction X and extends in the second direction Y. For example, one slit ST is located between the pixels PX1 and PX2, or between the lower electrodes LE2 and LE3 of the pixel PX1 and the lower electrode LE1 of the pixel PX2. Each of the illustrated pixels PX1, PX2, PX3, and PX4 is located between two slits ST adjacent to each other in the first direction X. These slits ST expose the insulating layer 5.

A width WS along the first direction X of the slit ST is smaller than the interval WX1 along the first direction X between the lower electrodes LE1 and LE2 (WS<WX1). The width WX11 along the first direction X of the segment DY2 is smaller than the width WS and is smaller than the interval WX1.

Of the detection electrode DT, each of the segments DX1, DX2, and DX3 extending in the first direction X overlaps the partition 6. Of the detection electrode DT, each of the segments DY1, DY2, and DY3 extending in the second direction Y overlaps the plurality of slits ST arranged in the second direction Y. Each of the segments DY1, DY2, and DY3 Is located at the center of the slit ST in the first direction X.

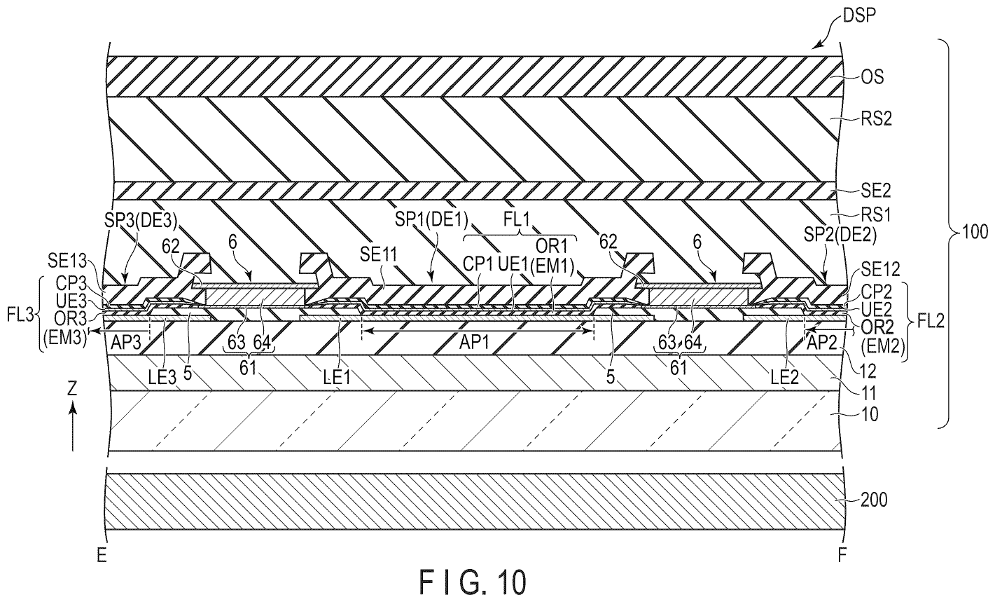

FIG. 10 is a schematic cross-sectional view of the display device DSP along the E-F line of FIG. 9. In the following, explanations that overlap those provided with reference to FIG. 4 may be omitted.

A circuit layer 11 is provided on the substrate 10. The insulating layer 12 is provided on the circuit layer 11. The lower electrode LE1 of the subpixel SP1, the lower electrode LE2 of the subpixel SP2, and the lower electrode LE3 of the subpixel SP3 are provided on the insulating layer 12.

The insulating layer 5 is an inorganic insulating layer and covers the insulating layer 12 and the periphery portions of the lower electrodes LE1, LE2, and LE3. The aperture AP1 of the insulating layer 5 overlaps the lower electrode LE1. The aperture AP2 overlaps the lower electrode LE2. The aperture AP3 overlaps the lower electrode LE3. The insulating layer 5 is formed of, for example, an inorganic insulating material such as a silicon nitride (SiNx) and a silicon oxynitride (SiON).

The partition 6 has a conductive lower portion 61 provided on the insulating layer 5 and an upper portion 62 provided on the lower portion 61.

In the illustrated example, the lower portion 61 has a bottom layer 63 provided on the insulating layer 5 and a stem layer 64 provided between the bottom layer 63 and the upper portion 62. The bottom layer 63 is thinner than the stem layer 64. The bottom layer 63 has the width greater than that of the stem layer 64. The both end portions of the bottom layer 63 protrude relative to the side surfaces of the stem layer 64.

The upper portion 62 is provided on the stem layer 64. The upper portion 62 has the width greater than that of the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and contacts the lower portion 61.

In the display element DE2, the organic layer OR2 contacts the lower electrode LE2 through the aperture AP2, covers the lower electrode LE2 exposed from the aperture AP2. The peripheral portion of the organic layer OR2 is located on the insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 has the cap layer CP1 and a sealing layer SE11. The subpixel SP2 has the cap layer CP2 and a sealing layer SE12. The subpixel SP3 has the cap layer CP3 and a sealing layer SE13. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

Each of the sealing layers SE11, SE12, and SE13 is formed of an inorganic insulating material such as a silicon nitride (SiNx), a silicon oxide (SiOx), a silicon oxynitride (SiON), or an aluminum oxide (Al₂O₃).

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12 and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Cavities are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. Further, the resin layer RS1 is filled into the cavity formed on the partition 6.

In the lower portion 61 of the partition 6, the bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is formed of a titanium-based material such as titanium or a titanium compound or an oxide conductive material such as indium tin oxide (ITO).

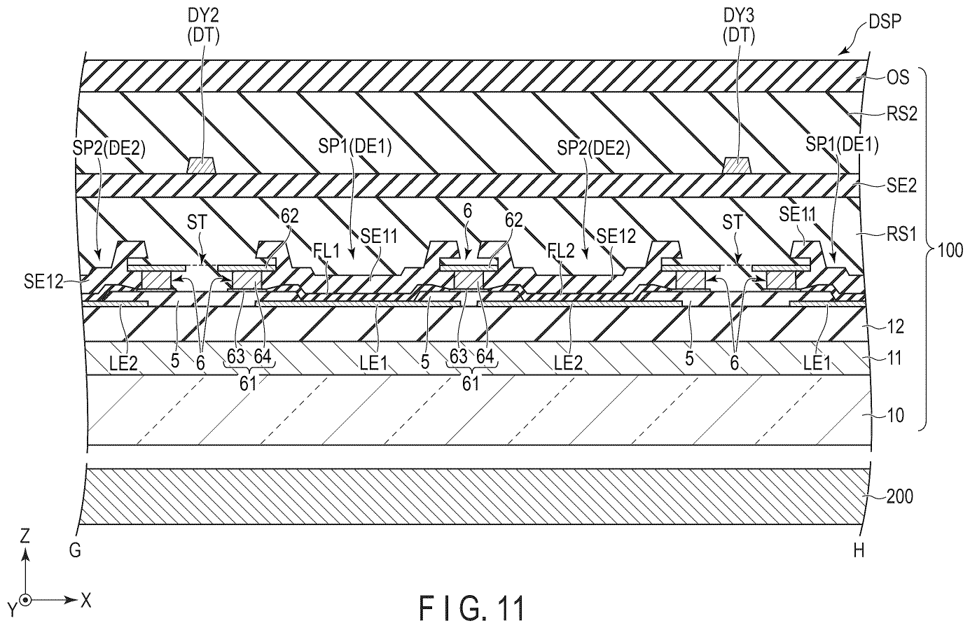

FIG. 11 is a schematic cross-sectional view of the display device DSP along the G-H line of FIG. 9.

The slit ST of the partition 6 corresponds to a portion that penetrates the bottom layer 63 and the stem layer 64 of the lower portion 61 and the upper portion 62. The resin layer RS1 is filled into the slit ST of the partition 6, covers the bottom layer 63, the stem layer 64, and the upper portion 62, and contacts the insulating layer 5.

The detection electrode DT including the segments DY2 and DY3 is provided on the sealing layer SE2 and is covered with the resin layer RS2. For example, the detection electrode DT is a multilayer body having an aluminum layer formed of an aluminum-based material and a titanium layer formed of a titanium-based material.

For example, in the subpixels SP1 and SP2 located at the center of the figure, the detection electrode DT is not provided in the area between the lower electrodes LE1 and LE2 and the area overlapping the slit ST. Thus, in the same manner as the configuration described with reference to FIG. 5, the light emitted from each of the subpixels SP1 and SP2 is less susceptible to shielding by the detection electrode DT. Thus, in the same manner as the above configuration example, undesirable decreases in luminance and undesirable variations in color chromaticity can be suppressed.

For example, in the subpixels SP1 and SP2 in the left side of the figure, the segment DY2 of the detection electrode DT is provided in the area between the lower electrodes LE1 and LE2 and the area overlapping the slit ST.

Similarly, in the subpixels SP1 and SP2 in the right side of the figure, the segment DY3 of the detection electrode DT is provided in the area between the lower electrodes LE1 and LE2 and the area overlapping the slit ST.

For example, the width of the segment DY is smaller than any of the interval between the lower electrodes LE1 and LE2 and the width of the slit ST. Thus, the transmissive area allowing the light Li to pass through can be formed in the area where the segment DY and the slit ST overlap.

Thus, in cases where the external device 200 is the optical device, the external device 200 can reliably receive the light Li having passed through the transmissive area and achieve desired performance.

Even in cases where the external device 200 is the communication device, the above transmissive area is formed as an area allowing radio waves to pass through. Thus, the external device 200 can reliably transmit or receive radio waves, achieving desired performance.

The display device DSP comprising the partition 6 described with reference to FIG. 9 to FIG. 11 can adopt the configuration example described with reference to FIG. 7 in which the segments DX extending in the first direction X are locally wide and the configuration example described with reference to FIG. 8 in which the segments DY extending in the second direction Y are formed discontinuously.

In the embodiment, for example, the lower electrode LE2 of the pixel PX1 corresponds to the first lower electrode, the lower electrode LE1 of the pixel PX2 corresponds to the second lower electrode, the lower electrode LE2 of the pixel PX2 corresponds to the third lower electrode, and the lower electrode LE1X corresponds to the fourth lower electrode.

The segment DY2 corresponds to the first segment, the segment DY3 corresponds to the second segment 2, the segment DX1 corresponds to the third segment, and the segment DX2 corresponds to the fourth segment.

The sealing layers SE1, SE11, SE12, and SE13 correspond to the first sealing layer, the resin layer RS1 corresponds to the first resin layer, the sealing layer SE2 corresponds to the second sealing layer, and the resin layer RS2 corresponds to the second resin layer.

In each of the pixels PX1, PX2, PX3, and PX4, the subpixel SP1 corresponds to the first subpixel, the subpixel SP2 corresponds to the second subpixel, and the subpixel SP3 corresponds to the third subpixel.

As described above, the embodiments can provide a display device that comprises a touch sensor function and is configured to improve display quality.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a first lower electrode, a second lower electrode, and a third lower electrode that are arranged in order in a first direction in a display area for displaying an image;
organic layers respectively provided on the first lower electrode, the second lower electrode, and the third lower electrode and each having a light emitting layer;
an upper electrode provided on the organic layer; and
a detection electrode for detecting contact or approach of an object to the display area, wherein
an interval along the first direction between the first lower electrode and the second lower electrode is greater than an interval along the first direction between the second lower electrode and the third lower electrode, and
the detection electrode extends in a second direction intersecting the first direction, includes a first segment located between the first lower electrode and the second lower electrode in plan view, and does not include a segment between the second lower electrode and the third lower electrode.

2. The display device of claim 1, wherein
the first segment is located at a center between the first lower electrode and the second lower electrode.

3. The display device of claim 1, wherein
a width along the first direction of the first segment is smaller than an interval along the first direction between the first lower electrode and the second lower electrode.

4. The display device of claim 1, wherein
the detection electrode further includes a second segment extending in the second direction and adjacent to the first segment in the first direction, and
the second lower electrode and the third lower electrode are located between the first segment and the second segment in plan view.

5. The display device of claim 4, wherein
the detection electrode further includes:
a third segment extending in the first direction; and
a fourth segment extending in the first direction and adjacent to the third segment in the second direction,
each of the third segment and the fourth segment intersects the first segment and the second segment, and
the second lower electrode and the third lower electrode are located between the third segment and the fourth segment in plan view.

6. The display device of claim 5, wherein
between the first segment and the second segment, each of the third segment and the fourth segment has:
a first portion adjacent to the second lower electrode in the second direction and having a first width; and
a second portion adjacent to the third lower electrode in the second direction and having a second width greater than the first width.

7. The display device of claim 1, further comprising:
a fourth lower electrode adjacent to the third lower electrode in the first direction, wherein
an interval along the first direction between the third lower electrode and the fourth lower electrode is greater than an interval along the first direction between the second lower electrode and the third lower electrode, and
the detection electrode does not have a segment between the third lower electrode and the fourth lower electrode.

8. The display device of claim 7, wherein
the detection electrode further includes:
a third segment extending in the first direction; and
a fourth segment extending in the first direction and adjacent to the third segment in the second direction, and
the first segment is located between the third segment and the fourth segment and does not extend beyond the third segment and the fourth segment.

9. The display device of claim 1, further comprising:
a first sealing layer formed of an inorganic insulating material and covering the upper electrode;
a first resin layer provided on the first sealing layer;
a second sealing layer formed of an inorganic insulating material and provided on the first resin layer; and
a second resin layer provided on the second sealing layer, wherein
the detection electrode is provided on the second sealing layer and is covered with the second resin layer.

10. The display device of claim 1, further comprising:
a partition that includes a lower portion having conductivity and contacting the upper electrode and an upper portion protruding relative to side surfaces of the lower portion and surrounds each of the first lower electrode, the second lower electrode, and the third lower electrode, wherein
the partition has a slit overlapping the first segment in plan view.

11. The display device of claim 10, wherein
the first segment is located at a center of the slit.

12. The display device of claim 10, wherein
the slit extends in the second direction between the first lower electrode and the second lower electrode, and
a width along the first direction of the slit is smaller than an interval along the first direction between the first lower electrode and the second lower electrode.

13. The display device of claim 10, wherein
the detection electrode further includes:
a third segment extending in the first direction; and
a fourth segment extending in the first direction and adjacent to the third segment in the second direction,
each of the third segment and the fourth segment intersects the first segment, and
each of the third segment and the fourth segment overlaps the partition in plan view.

14. The display device of claim 10, further comprising:
a first sealing layer formed of an inorganic insulating material, covering the upper electrode, and contacting the partition;
a first resin layer provided on the first sealing layer, filling the slit, and contacting the partition;
a second sealing layer formed of an inorganic insulating material and provided on the first resin layer; and
a second resin layer provided on the second sealing layer, wherein
the detection electrode is provided on the second sealing layer and is covered with the second resin layer.
